(19) United States
(12) Patent Application Publication
(10) Pub. No.: US 2006/0292884 A1
(43) Pub. Date: Dec. 28, 2006

(54) Method for fabricating semiconductor device

(75) Inventors: Ki-Won Nam, Kyoungki-do (KR); Sei-Jin Kim, Kyoungki-do (KR)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(73) Assignee: Hynix Semiconductor Inc.

(21) Appl. No.: 11/473,489

(22) Filed: Jun. 22, 2006

(30) Foreign Application Priority Data
Jun. 28, 2005 (KR) 2005-0056404

(51) Int. Cl. H01L 21/302; H01L 21/311

(52) U.S. Cl. 438/719; 438/742; 438/720; 438/694

(57) ABSTRACT

A method for fabricating a semiconductor device includes forming a polysilicon layer, a silicide layer and a hard mask over a semiconductor substrate, etching the silicide layer using the hard mask as an etch barrier, shaping the silicide layer with a predetermined profile using a mixed gas, and etching the polysilicon layer using the hard mask as an etch barrier.

### FIELD OF THE INVENTION

The present invention relates to a method for fabricating a semiconductor device, and more particularly, to a method for fabricating a semiconductor device using a step gated asymmetric recess (STAR) process.

### DESCRIPTION OF RELATED ARTS

As semiconductor devices are becoming highly integrated, such factors as an electric charge increase in a cell region and a refresh characteristic improvement have been directly related to reliability of semiconductor devices. To overcome limitations of the semiconductor devices, improving the refresh characteristic is essentially required.

Although the size of gates is often required to be increased to improve the refresh characteristic in a general semiconductor device fabricating process, there are limitations in the design rule, and in controlling of a boron concentration level in channel regions. Therefore, methods for increasing the length of gate channels have been suggested to maintain the boron concentration level, and to improve the refresh characteristic.

As one of the methods for increasing the length of the gate channels, a semiconductor device using a step gated asymmetric recess (STAR) process has been suggested, wherein an active region below the gates has a step structure.

FIG. 1A is a cross-sectional view illustrating a typical method for fabricating a semiconductor device. Device isolation regions 12 are formed in predetermined portions of a semiconductor substrate 11 using a shallow trench isolation (STI) process. STAR patterns 13 are formed by etching predetermined portions of the substrate 11 in a predetermined depth. The STAR patterns 13 are SNC node portions where storage nodes are to be connected to, and a remaining surface region 14 of the substrate 11, excluding the STAR patterns 13, is a BLC portion where a bit line is to be connected to. As described above, the STAR patterns 13 and the surface region 14 are formed with different heights.

A gate oxide layer 15 is formed on the above resulting substrate structure, and then, step gate lines SG are formed on the gate oxide layer 15, extending over both the STAR patterns 13 and the surface region.14. The step gate lines SG include a polysilicon layer 16, a silicide layer 17, and a hard mask nitride layer 18, formed in sequential order.

In the typical method, the step gate lines SG are formed to extend over portions of both the STAR patterns 13 and the surface region 14, lengthening channel regions defined below the step gate lines SG.

However, a landing plug contact (LPC) may not be opened properly during the typical method due to deformation of the step gate lines SG, causing a lack of an LPC open margin.

The reason for the occurrence of the LPC-not-open event is as follows. Thicknesses of the polysilicon layer 16 and the silicide layer 17 within portions of the active region increase as much as the etched depth of the STAR patterns 13 because the STAR patterns 13 are formed by etching the substrate 11 to improve the refresh characteristic, resulting in a lack of an etch target as much as the increased depth. Thus, excessive silicide oxidation occurs during a follow-up oxidation process after defining the step gate lines SG.

That is, due to the lack of the etch target, an exposed surface region on a lateral wall of the silicide layer 17 increases, and accordingly the length of the gate oxide layer 15 is increased during the oxidation process. Thus, a spacing distance becomes narrow between the step gate lines SG, resulting in a decreased open margin when etching the LPC.

If the etch target is increased as much as the length of the exposed surface region on the lateral wall of the silicide layer 17 to form an individual step gate line SG identical to the typical one, damage occurs to a bottom portion of the polysilicon layer 16, and thus, damage may occur to the active region when etching the polysilicon layer 16.

Such a loss of the polysilicon layer 16 reduces a process margin with respect to the gate oxide layer 15 at the bottom during an additional etching process of the polysilicon layer 16. As a result, the gate oxide layer 15 may be damaged.

FIG. 1B is a micrographic image of a typical semiconductor device with STAR structures. Excessive oxidation has occurred due to interfacial projections between a silicide layer and a polysilicon layer, and light oxidation. Thus, after forming a nitride layer for spacers in a cell region, the exposed surface region on the lateral wall of the silicide layer is formed in a concave shape, resulting in a narrow spacing distance between step gate lines. Especially, slopes ‘A’, as shown in FIGS. 1A and 1B, between the interfacial projections and the polysilicon layer decrease a spacing distance of contact holes at the bottom, resulting in a reduced LPC open margin.

FIG. 1C is a micrographic image illustrating a device where a silicide layer and a polysilicon layer are etched using the typical method. As shown, projections ‘B’ are formed on an interface between the silicide layer and the polysilicon layer. The polysilicon layer is formed along the projections ‘B’.

According to the typical method, one of the reasons that the LPC-not-open event occurs is because the silicon substrate etching (i.e., the STAR process) for improving the refresh characteristic of the device may cause the thicknesses of the polysilicon layer and the silicide layer to increase as much as the etched depth of the silicon substrate within portions of the active regions, and thus, there is often a lack of an etch target as much as the increased depth.

Due to the abnormal slopes forming on the interface between the silicide layer and the polysilicon layer, performing an oxidation process after defining the gate pattern results in an oxidation level of the silicide layer to become excessive, and consequently, the oxide layer is lengthened as compared with the typical one.

The interfacial projections are generated between the silicide layer and the polysilicon layer, resulting in a decreased spacing distance between the gate patterns. Thus, the open margin may also be decreased when the etching process for the LPC is performed.

When performing the typical STAR process in a 100 nm or below level dynamic random access memory (DRAM), limitations such as an LPC-not-open event may occur due to a lack of LPC open margin caused by a sloped gate pattern profile.

### SUMMARY OF THE INVENTION

It is, therefore, an object of the present invention to provide a method for fabricating a semiconductor device capable of improving a landing plug contact (LPC) open margin by preventing gate pattern deformation, which is caused by interfacial projections formed on a gate electrode polysilicon layer, and excessive silicide layer oxidation.

In accordance with an aspect of the present invention, there is provided a method for fabricating a semiconductor device, including: forming a polysilicon layer, a silicide layer and a hard mask over a semiconductor substrate; etching the silicide layer using the hard mask as an etch barrier; shaping the silicide layer with a predetermined profile using a mixed gas; and etching the polysilicon layer using the hard mask as an etch barrier.

### BRIEF DESCRIPTION OF THE DRAWINGS

The above and other objects and features of the present invention will become better understood with respect to the following description of the specific embodiments given in conjunction with the accompanying drawings, in which:

FIG. 1A is a cross-sectional view illustrating a typical method for fabricating a semiconductor device;

FIG. 1B is a micrographic image illustrating a typical semiconductor device with STAR structures;

FIG. 1C is a micrographic image illustrating a device where a silicide layer and a polysilicon layer are etched using the typical method;

FIG. 2 is a cross-sectional view illustrating a method for fabricating a semiconductor device in accordance with a specific embodiment of the present invention; and

FIG. 3 is a micrographic image of the semiconductor device shown in FIG. 2.

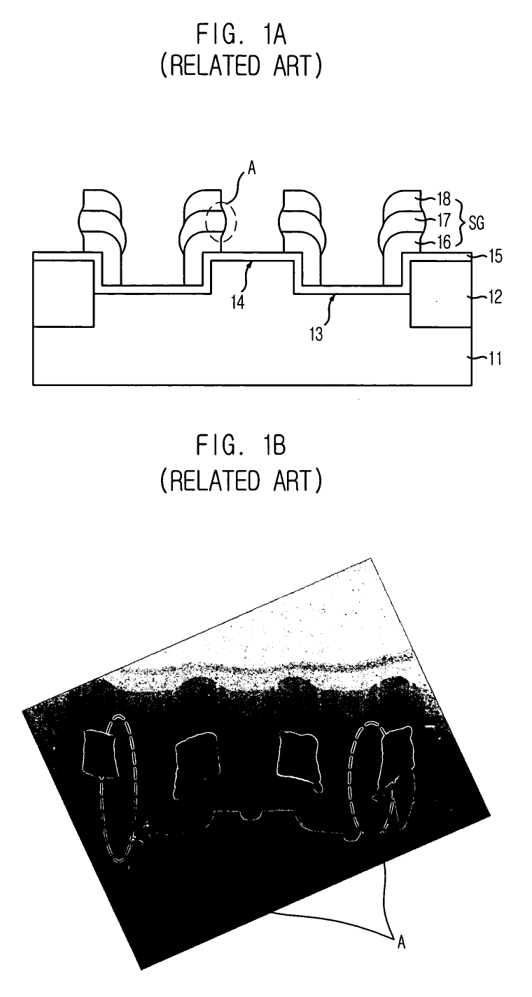

### DETAILED DESCRIPTION OF THE INVENTION

A method for fabricating a semiconductor device in accordance with specific embodiments of the present invention will be described in detail with reference to the accompanying drawings.

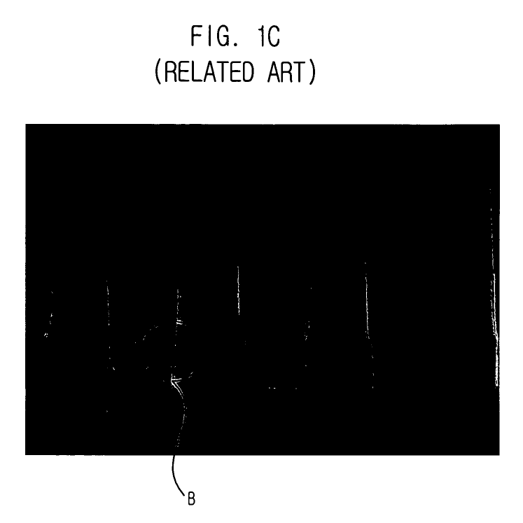

FIG. 2 is a cross-sectional view illustrating a method for fabricating a semiconductor device in accordance with a specific embodiment of the present invention. Device isolation regions 22 are formed in predetermined portions of a semiconductor substrate 21 using a shallow trench isolation (STI) process. Step gated asymmetric recess (STAR) patterns 23 are formed to a predetermined depth by etching predetermined portions of the substrate 21. The STAR patterns 23 are storage node contact (SNC) node portions where storage nodes are to be connected to, and a remaining surface region 24 of the substrate 21, excluding the STAR patterns 23, is a bit line contact (BLC) portion where a bit line is to be connected to. The STAR patterns 23 and the surface region 24 are formed with different heights.

A gate oxide layer 25 is formed on the above resulting substrate structure, and then, step gate lines SG are formed on the gate oxide layer 25, extending over both the STAR patterns 23 and the surface region 24. Each of the step gate lines SG include a polysilicon layer 26, a silicide layer 27, and a hard mask nitride layer 28, formed in sequential order.

The step gate lines SG have a vertical profile. While forming the step gate lines SG, the metal silicide layer 27 is etched more than the polysilicon layer 26 such that the metal silicide layer 27 is negatively bowed, and thus, the vertical profile is achieved. During the aforementioned process, a sputtering effect provided by a mixed etching gas should be maximized between word lines. The sputtering effect induces the silicide layer 27 to form with a negatively bowing profile.

Meanwhile, after the silicide layer 27 is etched, predetermined portions of the silicide layer 27 and the polysilicon layer 26 are additionally etched to maximize the sputtering effect by the mixed etching gas. The polysilicon layer 26 is inevitably etched during the etching of the silicide layer 27. The portions of the silicide layer 27 are etched under a target of removing a thickness equivalent to approximately 200 Å of the polysilicon layer 26 in a cell region.

To obtain the sputtering effect, a top radio frequency (RF) plasma power is supplied in a range of approximately 100 W to approximately 300 W and a bottom RF plasma power is supplied in a range of approximately 20 W to approximately 100 W in a chamber, and the mixed etching gas has a ratio of a chlorine-based gas to oxygen gas ranging from approximately 5:1 to approximately 3:1. The mixed etching gas flows in a total quantity of approximately 40 sccm.

If the silicide layer 27 is etched under the above conditions, the negatively bowing profile of the silicide layer 27 may become relatively sharpened due to the sputtering effect. Herein, a small quantity of hydrogen bromide (HBr) or nitrogen (N₂) is added for a slight passivation effect.

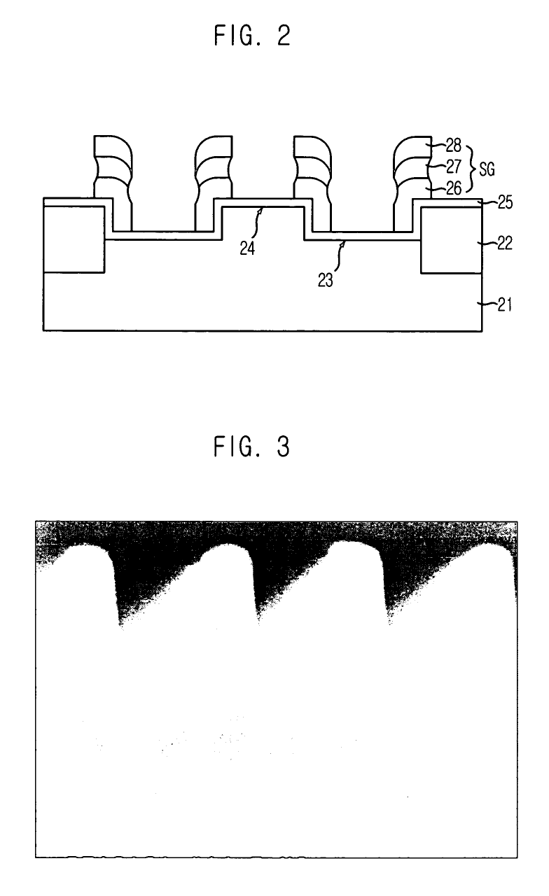

FIG. 3 is a micrographic image of the semiconductor device in FIG. 2. By forming or shaping the silicide layer with the negatively bowing profile using the sputtering effect obtained by employing the mixed etching gas for the etching of the silicide layer, the interfacial projections formed between the silicide layer and the polysilicon layer are removed, and the polysilicon layer can be formed in a vertical shape.

According to the specific embodiment of the present invention, a certain spacing distance between the gate patterns can be maintained, and thus, the LPC-not-open event can be prevented while forming the landing plug contact.

The present application contains subject matter related to the Korean patent application No. KR 2005-0056404, filed in the Korean Patent Office on Jun. 28, 2005, the entire contents of which being incorporated herein by reference.

While the present invention has been described with respect to certain specific embodiments, it will be apparent to those skilled in the art that various changes and modifications may be made without departing from the spirit and scope of the invention as defined in the following claims.

What is claimed is:

1. A method for fabricating a semiconductor device, the method comprising:
forming a polysilicon layer, a silicide layer and a hard mask over a semiconductor substrate;
etching the silicide layer using the hard mask as an etch barrier;
shaping the silicide layer with a predetermined profile using a mixed gas; and
etching the polysilicon layer using the hard mask as an etch barrier.

2. The method of claim 1, wherein the mixed gas includes a chlorine-based gas and oxygen gas.

3. The method of claim 1, wherein the shaping of the silicide layer with the predetermined profile using the mixed gas uses a radio frequency (RF) plasma power supplied in a range of approximately 100 W to approximately 300 W.

4. The method of claim 1, wherein the shaping of the silicide layer with the predetermined profile using the mixed gas uses a RF plasma power supplied in a range of approximately 20 W to approximately 100 W.

5. The method of claim 2, wherein the mixed gas has a ratio of the chlorine-based gas to the oxygen gas ranging from approximately 5:1 to approximately 3:1.

6. The method of claim 1, wherein the mixed gas flows in a total quantity of approximately 40 sccm.

7. The method of claim 2, wherein the mixed gas flows in a total quantity of approximately 40 sccm.

8. The method of claim 1, wherein the shaping of the silicide layer with the predetermined profile using the mixed gas utilizes an ion sputtering method.

9. The method of claim 1, wherein the shaping of the silicide layer with the predetermined profile further comprises employing a polymer hatching gas when the profile of the silicide layer is negatively bowed by the ion sputtering method.

10. The method of claim 9, wherein the polymer hatching gas includes hydrogen bromide (HBr) gas and a nitride-based gas.

11. The method of claim 1, wherein the shaping of the silicide layer with the predetermined profile includes removing a target thickness of the silicide layer equivalent to approximately 200 Å of the polysilicon layer.

12. The method of claim 1, wherein the predetermined profile of the silicide layer is a negative bow.
